(19) United States
(12) Patent Application Publication
(10) Pub. No.: US 2015/0102457 A1
(43) Pub. Date: Apr. 16, 2015

(54) SEMICONDUCTOR DEVICE

(71) Applicant: FUJI ELECTRIC CO., LTD., Kawasaki-shi (JP)

(72) Inventors: Akihiro JONISHI, Matsumoto-city (JP); Hiroshi KANNO, Matsumoto-city (JP)

(21) Appl. No.: 14/484,360

(22) Filed: Sep. 12, 2014

(30) Foreign Application Priority Data
Oct. 15, 2013 (JP) 2013-215128

(51) Int. Cl. H01L 23/525; H01L 49/02

(52) U.S. Cl. CPC H01L 23/5256; H01L 28/20
USPC 257/529

(57) ABSTRACT

A polysilicon resistor includes a high resistance conductor, a low resistance conductor adjacent to one end portion of the high resistance conductor, and a low resistance conductor adjacent to the other end portion of the high resistance conductor. Of the high resistance conductor, a width of a first place reacting most actively when a current flows into a polysilicon fuse is narrowest. Of the high resistance conductor, a width of a second place serving as an interface with each of the low resistance conductors is widest. The width of the high resistance conductor increases gradually from the first place toward the second place.

### CROSS-REFERENCE TO RELATED APPLICATION

This application claims priority from and the benefit of Japanese Application No. 2013-215128, filed Oct. 15, 2013, the entire disclosure of which is incorporated herein by reference.

### BACKGROUND OF THE INVENTION

1. Field of the Invention

Embodiments of the invention relate to a semiconductor device.

2. Discussion of the Background

Trimming using a polysilicon fuse whose resistance value can be adjusted is known as a method for adjusting the characteristic of a semiconductor integrated circuit. The polysilicon fuse has a resistor made from polysilicon (hereinafter referred to as polysilicon resistor) and is used for data writing etc. for adjusting the characteristic of the circuit. In the trimming using the polysilicon fuse, a comparatively large current is applied to the polysilicon resistor to heat the polysilicon resistor to a melting point or higher so that a part of the polysilicon resistor serving as a current path can be changed to an insulator such as silicon oxide or a gap. Thus, the resistance value of the polysilicon fuse can be increased.

The polysilicon fuse may be configured so that the resistance value of the polysilicon fuse can be changed by a low voltage, which is available internally in the semiconductor integrated circuit. Thus, there is an advantage that the degree of freedom in design for timing to trim the polysilicon fuse or a unit for applying a current to the polysilicon fuse can be improved so that, for example, even after the polysilicon fuse is incorporated into a package, the polysilicon fuse can be trimmed by a low voltage used internally in the semiconductor integrated circuit to thereby adjust the characteristic of the circuit.

A device provided with a polysilicon fuse including a polysilicon resistor and contact electrodes has been proposed as a semiconductor device provided with a polysilicon fuse whose resistance value can be increased by a low voltage (for example, see JP-A-2000-40790). The polysilicon resistor has a locally narrow width region (portion having a small sectional area). Each of the contact electrodes has a planar shape which is partially hollowed out substantially into a semicircle, so that the contact electrodes can be arranged substantially concentrically in positions at a predetermined distance from the narrow width region of the polysilicon resistor. In JP-A-2000-40790, the distance between the narrow width region of the polysilicon resistor and each contact electrode is made constant so that a current can be concentrated in the narrow width region of the polysilicon resistor.

Although a heating place is concentrated in the narrow width region of the polysilicon resistor to melt down the polysilicon resistor in JP-A-2000-40790, there is a fear that sufficient reliability cannot be obtained depending on the state of the melted-down portion of the polysilicon resistor. The reason is as follows. The background-art semiconductor integrated circuit may be often operated in a state in which a voltage is applied to the polysilicon fuse. Therefore, the melted-down portion may serve as a current path depending on the state of the melted-down portion of the polysilicon resistor. Accordingly, a leak current may flow all over the polysilicon fuse to generate heat therein. Thus, there is a fear that the state of the polysilicon fuse may change to a different state from the state at the time of product shipment. That is, there is a problem that the polysilicon fuse has low long-term reliability for long-term use.

To trim the polysilicon fuse in order to prevent such a problem, a part of the polysilicon resistor needs to be changed to an insulator or a gap so that the polysilicon resistor can be cut off surely, and the distance between the polysilicon resistor parts opposed to each other with respect to the part replaced by the insulator or the gap needs to be secured as long as possible (for example, see “Novel surface-micromachined low-power fuses for on-chip calibration” D. Maier-Schneider et al., Germany, in Sensors and Actuators A: Physical, Elsevier, Volumes 97-98 (2002), pages 173-178). In the “Novel surface-micromachined low-power fuses for on-chip calibration”, a part of the polysilicon resistor is changed to a gap to increase the resistance value of the polysilicon fuse. The polysilicon fuse shown in the “Novel surface-micromachined low-power fuses for on-chip calibration” will be described with reference to FIGS. 9 to 11. FIGS. 9 to 11 correspond to FIGS. 1 and 2 in the “Novel surface-micromachined low-power fuses for on-chip calibration”.

FIG. 9 is a plan view showing a planar structure of a polysilicon fuse according to the background art. FIG. 10 is a perspective view showing a structure of a semiconductor device provided with the polysilicon fuse in FIG. 9. FIG. 11 is a plan view showing the structure of the semiconductor device in the periphery of the polysilicon fuse in FIG. 10. As shown in FIGS. 9 to 11, the polysilicon fuse according to the background art is constituted by a polysilicon resistor 102 which is provided on a semiconductor substrate 101 through an LOCOS film (not shown). The polysilicon resistor 102 has a planar shape in which a width (lateral length) w102-1 of a first part 102-1 to be melted down is made narrower than a width w102-2 of each of the other second parts 102-2.

The planar shape of the first part 102-1 of the polysilicon resistor 102 is substantially formed into an elongated rectangular shape. Specifically, the first part 102-1 of the polysilicon resistor 102 has a longitudinal length l102-1 of about 3 the lateral length (width) w102-1 of about 1 and a thickness t101 of about 0.5 μm. The resistance value of the polysilicon fuse which has not been melted down is about 200 Ω. The resistance value of the polysilicon fuse which has been melted down by a voltage 4V is, for example, 10 GΩ or higher. In order to melt the polysilicon resistor 102 by a low voltage, a cavity 103 formed by removing an oxide film 104 is provided in the periphery of the first part 102-1 of the polysilicon resistor 102.

To form the cavity 103 in the periphery of the first part 102-1 of the polysilicon resistor 102, a step of forming an etching mask used as a mask when the cavity 103 is formed in the oxide film 104 by etching is added in a general CMOS process. In addition, when the oxide film 104 is etched, a polysilicon film 105 used as a cover plate of the polysilicon resistor 102 is formed above the first part 102-1 of the polysilicon resistor 102. Processing required for forming the cavity 103 by etching is applied to the polysilicon film 105. Reference numeral 106 designates an oxide film; and reference numeral 107 designates a passivation film.

The cavity 103 has smaller thermal conductivity and less heat dissipation, in comparison with the oxide film 104. Therefore, in the semiconductor device shown in FIGS. 9 to 11, energy supplied from the outside for melting down the polysilicon resistor 102 is smaller than that in the case where the periphery of the polysilicon resistor is covered with the oxide film so that the first part 102-1 of the polysilicon resistor 102 can be melted down (burned off) by a low voltage. In addition, the cavity 103 has a sufficient space into which a melted-down portion of the polysilicon resistor 102 can flow. The melted-down polysilicon flows down so as not to remain between the second parts 102-2 of the polysilicon resistor 102. Therefore, the first part 102-1 of the polysilicon resistor 102 can be more reliably replaced by a gap.

However, in the aforementioned “Novel surface-micromachined low-power fuses for on-chip calibration”, there is a problem that the cost increases for the two following reasons. The first reason is that the etching mask used for forming the cavity 103 by etching is required as described above. The second reason is that the cavity 103 is widened in order to form the space into which the melted polysilicon can flow so that the area of the polysilicon film 105 used as the cover plate of the polysilicon resistor 102 is required to be widened accordingly (for example, 30 μm×30 μm in the “Novel surface-micromachined low-power fuses for on-chip calibration”) with a result that the size of the polysilicon fuse is larger than that of an ordinary polysilicon fuse whose periphery is covered with an oxide film.

### SUMMARY

Embodiments of the invention provide a semiconductor device provided with an inexpensive and highly reliable fuse.

A semiconductor device according to an embodiment of the invention has the following characteristics. An insulating film is provided on a semiconductor substrate. A fuse is provided on the insulating film. An oxide film which covers the fuse is provided. The fuse includes a first resistor, a second resistor and a third resistor. The second resistor is adjacent to one end portion of the first resistor. The third resistor is adjacent to the other end portion of the first resistor. The second resistor and the third resistor have lower resistance than the first resistor. The width of the first resistor decreases gradually from the second resistor side and the third resistor side toward a predetermined place.

In addition, according to an embodiment of the invention, there is provided a semiconductor device having the aforementioned configuration, wherein: the first resistor has such a planar shape that two trapezoidal shape parts each of which includes the predetermined place as an upper bottom and an interface with the second resistor or an interface with the third resistor as a lower bottom are arranged so that the upper bottoms can face each other.

In addition, according to an embodiment of the invention, there is provided a semiconductor device having the aforementioned configuration, wherein: an angle between a side surface of one trapezoidal shape part including an interface between the first resistor and the second resistor as a lower bottom and a side surface of the other trapezoidal shape part including an interface between the first resistor and the third resistor as a lower bottom is larger than 90°.

In addition, according to an embodiment of the invention, there is provided a semiconductor device having the aforementioned configuration, wherein: a current flows in the fuse along a current path from the second resistor toward the third resistor through the first resistor; and the predetermined place of the first resistor is a place where heat is generated most due to the flowing of the current.

In addition, according to an embodiment of the invention, there is provided a semiconductor device having the aforementioned configuration, wherein: the width of the first resistor in a direction perpendicular to the current path is narrower than each of the widths of the second resistor and the third resistor in the direction perpendicular to the current path.

In addition, according to an embodiment of the invention, there is provided a semiconductor device having the aforementioned configuration, wherein: a plurality of first resistors each having the same configuration as the first resistor are formed in parallel with one another in a direction perpendicular to a current path. In addition, according to an embodiment of the invention, there is provided a semiconductor device having the aforementioned configuration, wherein: each first resistor is made from polycrystalline silicon.

According to the aforementioned configurations, the distance between blown faces of the fuse can be made longer than that according to the background art, in spite of a low voltage (for example, about 5V to 10V) used internally in a semiconductor integrated circuit. Thus, the fuse can be blown more surely than that according to the background-art structure. In addition, according to embodiments of the invention, an etching mask used in an etching process for making a cavity in the periphery of the fuse or a cover plate of the polysilicon resistor is dispensable. Thus, the cost can be prevented from increasing.

According to the semiconductor device according to embodiments of the invention, it is possible to achieve an effect that a semiconductor device provided with a highly reliable fuse can be provided inexpensively.

### BRIEF DESCRIPTION OF THE DRAWINGS

FIG. 1 is a perspective view showing a structure of a polysilicon fuse provided in a semiconductor device according to Embodiment 1.

FIG. 2 is a plan view showing a planar structure of the polysilicon fuse according to Embodiment 1.

FIG. 3 is a plan view showing a state in which the polysilicon fuse in FIG. 2 has been blown.

FIG. 4 is a plan view showing a planar structure of a polysilicon fuse according to the background art.

FIG. 5 is a plan view showing a state in which the polysilicon fuse in FIG. 4 has been blown.

FIGS. 6A and 6B are plan views showing a half part of a high resistance conductor of a polysilicon resistor constituting a polysilicon fuse in a semiconductor device according to an embodiment of the invention and the background art, respectively.

FIG. 7 is a plan view showing a planar structure of a polysilicon fuse provided in a semiconductor device according to Embodiment 2.

FIG. 8 is a plan view showing a planar structure of another example of the polysilicon fuse provided in the semiconductor device according to Embodiment 2.

FIG. 9 is a plan view showing a planar structure of a plolysilicon fuse according to the background art.

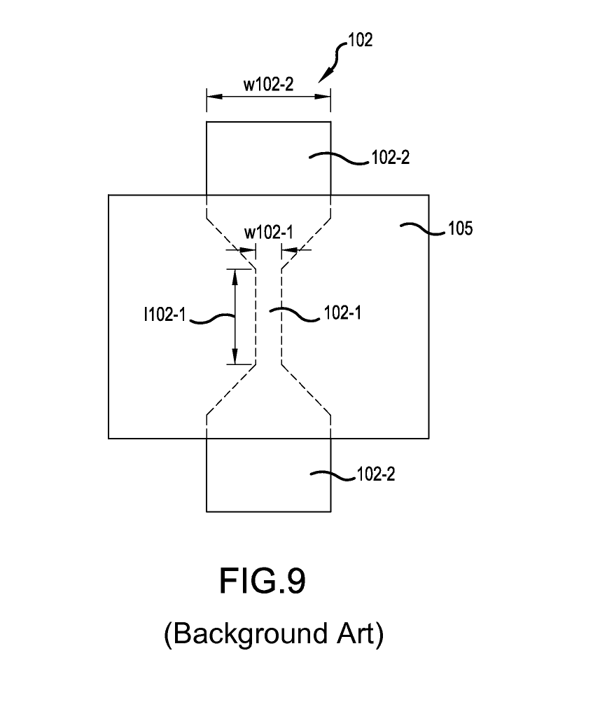

FIG. 10 is a perspective view showing a structure of a semiconductor device provided with the polysilicon fuse in FIG. 9.

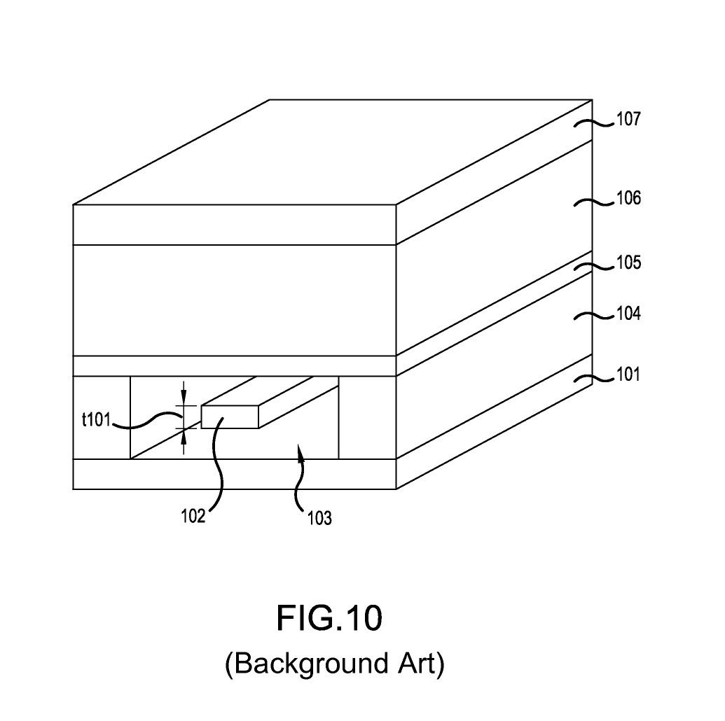

FIG. 11 is a plan view showing the structure of the semiconductor device in the periphery of the polysilicon fuse in FIG. 10.

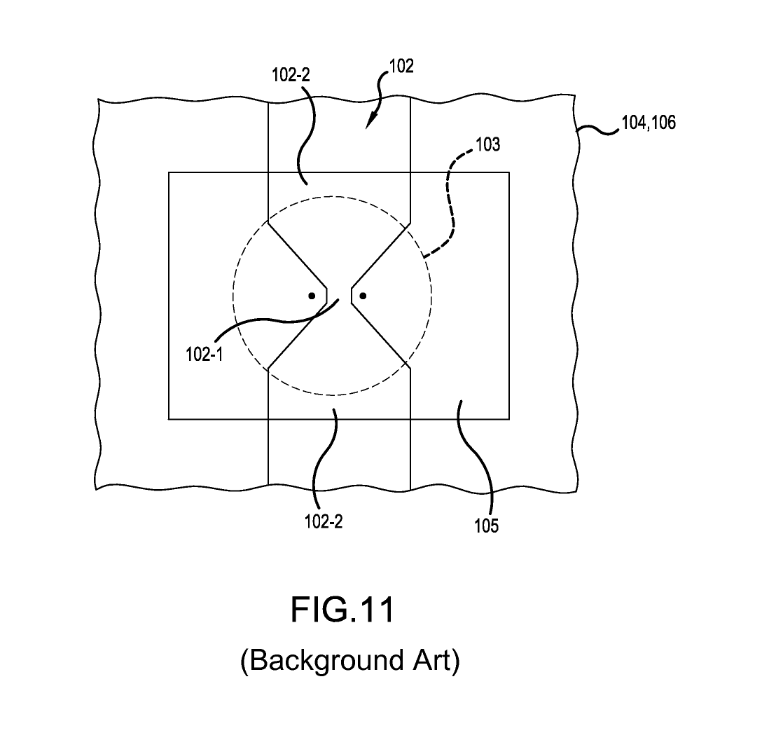

### DETAILED DESCRIPTION OF ILLUSTRATED EMBODIMENTS

A semiconductor device according to embodiments of the invention will be described below in detail with reference to the accompanying drawings. Incidentally, in the following description about the embodiments and the accompanying drawings, similar constituents will be given the same reference numerals correspondingly so that duplicate description thereof will be omitted. In addition, in the accompanying drawings, each configuration of the semiconductor device according to this invention will be illustrated with different dimensions from real dimensions in order to make it easy to view the configuration.

### Embodiment 1

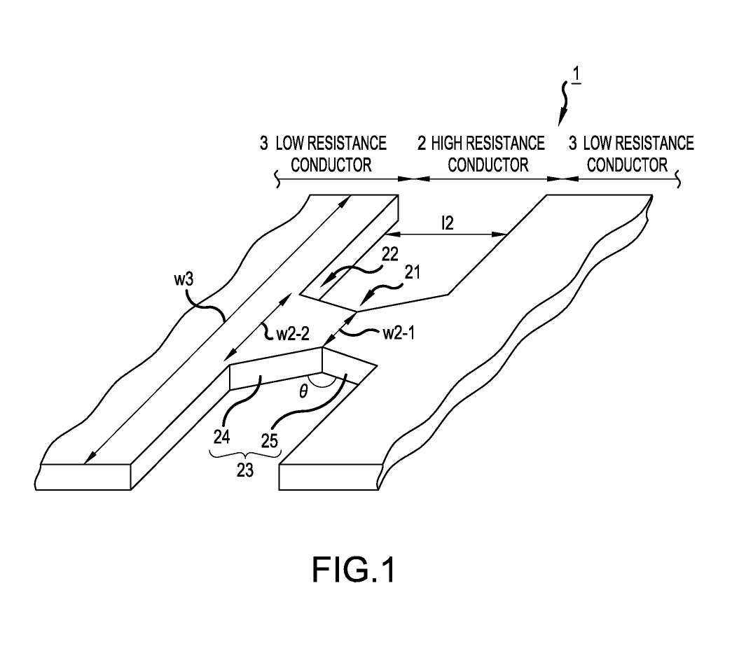

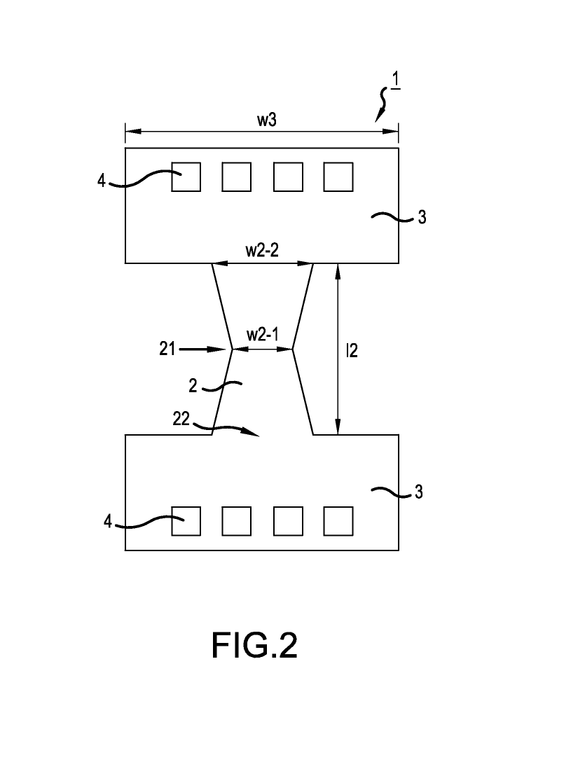

A structure of a semiconductor device according to Embodiment 1 will be described. FIG. 1 is a perspective view showing a structure of a polysilicon fuse provided in the semiconductor device according to Embodiment 1. FIG. 2 is a plan view showing a planar structure of the polysilicon fuse according to Embodiment 1. The semiconductor device according to Embodiment 1 is provided with a plurality of polysilicon fuses each having the same structure as shown in FIGS. 1 and 2. The polysilicon fuses constitute a storage portion (memory) which, for example, uses each polysilicon fuse as one bit to write data based on whether the polysilicon fuse has been blown or not. The polysilicon fuses are provided on a semiconductor substrate (not shown) through an LOCOS film (local insulating film). That is, the polysilicon fuses are disposed in a portion in which a top-surface element structure (not shown) of a semiconductor element such as an insulated-gate field-effect transistor (MOSFET) on the semiconductor substrate is not provided.

Each of the polysilicon fuses is constituted, for example, by a resistor (hereinafter referred to as polysilicon resistor) 1 made from polysilicon (polycrystalline silicon). The polysilicon resistor 1 is formed, for example, by use of a polysilicon layer formed by a general semiconductor manufacturing process. The polysilicon resistor 1 is covered, for example, with a silicon oxide film (SiO₂ film). In addition, the polysilicon resistor 1 includes a relatively high resistance part (hereinafter referred to as first resistor serving as high resistance conductor) 2 and relatively low resistance parts (hereinafter referred to as second and third resistors serving as low resistance conductors) 3. Specifically, for example, the polysilicon resistor 1 includes a high resistance conductor 2, a low resistance conductor (second resistor) 3 adjacent to one end portion of the high resistance conductor 2, and a low resistance conductor (third resistor) 3 adjacent to the other end portion of the high resistance conductor 2. During trimming of the polysilicon fuse, a current flows in the polysilicon resistor 1 along a current path from one low resistance conductor 3 toward the other low resistance conductor 3 through the high resistance conductor 2. A width w2-1 or 2-2 (which will be described later in detail) of the high resistance conductor 2 is made narrower than a width (length in a direction perpendicular to the current path of the polysilicon resistor 1, hereinafter simply referred to as width) w3 of each of the low resistance conductors 3. Accordingly, the resistance of the high resistance conductor 2 is made higher than that of the low resistance conductor 3, so that the current can be concentrated to increase the temperature easily in the high resistance conductor 2.

Of the high resistance conductor 2, the width w2-1 of a first place (for example, a central portion of the high resistance conductor 2 in a direction parallel to the current path of the polysilicon resistor 1) 21, which reacts most actively when the current flows into the polysilicon fuse, is narrowest. In addition, of the high resistance conductor 2, the width w2-2 of each second place 22, which serves as an interface with the corresponding low resistance conductor 3, is widest. The expression “the polysilicon resistor 1 reacts” means that Joule heat is generated in the polysilicon resistor 1 when a voltage is applied to the polysilicon resistor 1 during trimming of the polysilicon fuse. The first place 21 is the most actively reacting place where polysilicon is melted or melted and evaporated due to the generation of the heat. A polysilicon fuse trimming mechanism is described below.

The width of the high resistance conductor 2 may increase gradually from the first place 21 toward the second place 22. That is, the high resistance conductor 2 may have such a planar shape that parts (hereinafter referred to as trapezoidal shape parts), each having a trapezoidal planar shape including the first place 21 as an upper bottom and the second place 22 as a lower bottom, are arranged in linear symmetry using the upper bottoms as symmetry axes so that the upper bottoms of the trapezoidal shape parts can face each other. This is because of the following three reasons.

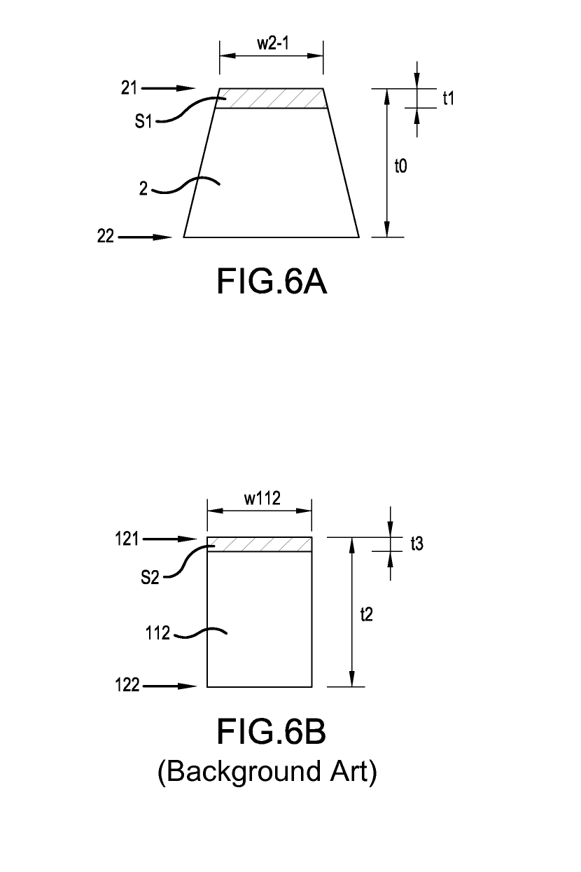

The first reason is that the polysilicon resistor 1 can be cut off more surely than the background-art structure in which the planar shape of the high resistance conductor is substantially formed into a rectangular shape (hereinafter simply referred to as background-art structure). Specifically, the length (length in the direction parallel to the current path of the polysilicon resistor 1, hereinafter simply referred to as length) of a gap portion formed due to contraction of the polysilicon as a result of melting the vicinity of the first place 21 of the high resistance conductor 2 during trimming of the polysilicon fuse, that is, the height of the trapezoidal shape of the gap portion including the first place 21 as the upper bottom is longer than the length of the melting portion of the high resistance conductor in the background-art structure (see the description as to FIGS. 6A and 6B, described below). Thus, the distance between cut faces of the polysilicon resistor 1 cut off due to the trimming can be made longer than that in the background-art structure. Accordingly, the resistance of the portion put between the cut faces of the polysilicon resistor 1 can be made higher than that in the background-art structure.

The second reason is that the first place 21 of the high resistance conductor 2 can be melted down easily. Specifically, when, for example, the width of the high resistance conductor 2 is increased stepwise from the first place 21 toward the second place 22, a place (the first place 21) where heat is generated most and a place where the electric field is concentrated are displaced from each other because the place where the electric field is concentrated corresponds to a corner portion of each step. On the other hand, when the planar shape of the high resistance conductor 2 is formed into a trapezoidal planar shape, which is widened gradually from the first place 21 toward the second place 22, a place where heat is generated most and a place where the electric field is concentrated can be made coincident with each other because the electric field is concentrated in the first place 21. Accordingly, the first place 21 of the high resistance conductor 2 can be melted down easily.

The third reason is that the size of the high resistance conductor 2 can be set to be the smallest size determined based on design criteria (design rules). Specifically, when, for example, the width of the high resistance conductor 2 is increased stepwise from the first place 21 toward the second place 22, the length of each step needs to be set to be, for example, at least about 1 which is the minimum value determined based on the design criteria. Therefore, even when the width of the high resistance conductor 2 is increased by one step from the first place 21 toward the second place 22, the length of the first place 21, the length of the step on the side of one of the low resistance conductors 3 between which the first place 21 is interposed, and the length of the step on the side of the other of the low resistance conductors 3 between which the first place 21 is interposed need to be set to be a minimum value (for example, 1 μm) respectively based on the design criteria. The length l2 of the high resistance conductor 2 can be at least 3 μm.

On the other hand, when the planar shape of the high resistance conductor 2 is formed into the trapezoidal planar shape widened gradually from the first place 21 toward the second place 22, the length, which is half the length l2 of the high resistance conductor 2 corresponding to the height of the trapezoidal shape part of the high resistance conductor 2, can be set to be a minimum value (for example, 1 μm) based on the design criteria. Accordingly, the length l2 of the high resistance conductor 2 can be set to be at least 2 μm. Incidentally, when the length l2 of the high resistance conductor 2 is too short, melted polysilicon in the vicinity of the first place 21 of the high resistance conductor 2 is difficult to move during trimming of the polysilicon fuse so that a gap cannot be easily generated in the vicinity of the first place 21 of the high resistance conductor 2. On the other hand, when the length l2 of the high resistance conductor 2 is too long, the resistance of the high resistance conductor 2 becomes so high that it is necessary to apply a high voltage in order to melt down the high resistance conductor 2. Therefore, the length l2 of the high resistance conductor 2 may be made long enough to melt down the high resistance conductor 2 at a desired voltage. Specifically, the length l2 of the high resistance conductor 2 may be, for example, about 2 μm which is, for example, the minimum value determined based on the design criteria.

In addition, when the planar shape of the high resistance conductor 2 is formed into a trapezoidal planar shape widened gradually from the first place 21 toward the second place 22, the first place 21 serving as the interface between the upper bottoms of the two trapezoidal shape parts is set as an intersection line in each side surface 23 of the high resistance conductor 2, and an angle θ between a side surface 24 of one trapezoidal shape part and a side surface 25 of the other trapezoidal shape part may be larger than 90°. The reason is as follows. When the angle θ is not larger than 90°, the distance between the side surface 24 of one trapezoidal shape part and the side surface 25 of the other trapezoidal shape part is too short. Therefore, during long-term use as a product, there is a fear that long-term reliability may be deteriorated, for example, due to a leak current occurring from one low resistance conductor 3 toward the other low resistance conductor 3. Further, the angle θ may be set to be not smaller than 120°. On the other hand, the angle θ may be set to be not larger than 150° so that the first place 21 can be melted down easily.

A plurality of contact electrodes 4 for connecting the polysilicon resistor 1 to electrodes constituting the top-surface element structure are adjacent to the low resistance conductors 3. For example, the contact electrodes 4 are provided inside contact holes provided in the silicon oxide film covering the polysilicon resistor 1. For example, each of the contact electrodes 4 is connected to a gate electrode of an MOSFET, a drain electrode of a p-channel type MOSFET, or the like, which functions as a switch for trimming the polysilicon fuse. By ON/OFF of the MOSFET functioning as a switch, a current can flow between the contact electrodes 4 and the contact electrodes 4 opposed to each other with respect to the high resistance conductor 2. The contact electrodes 4 are arranged in positions, for example, at a distance of about 1 μm, for example, from the second place 22 serving as the interface between the high resistance conductor 2 and each of the low resistance conductors 3. The arrangement of the contact electrodes 4 may be changed variously. However, as the distance between the contact electrodes 4 and the high resistance conductor 2 is shorter, the first place 21 of the high resistance conductor 2 generates heat more easily. Therefore, the contact electrodes 4 may be arranged in parallel with the interface between the high resistance conductor 2 and each of the low resistance conductors 3.

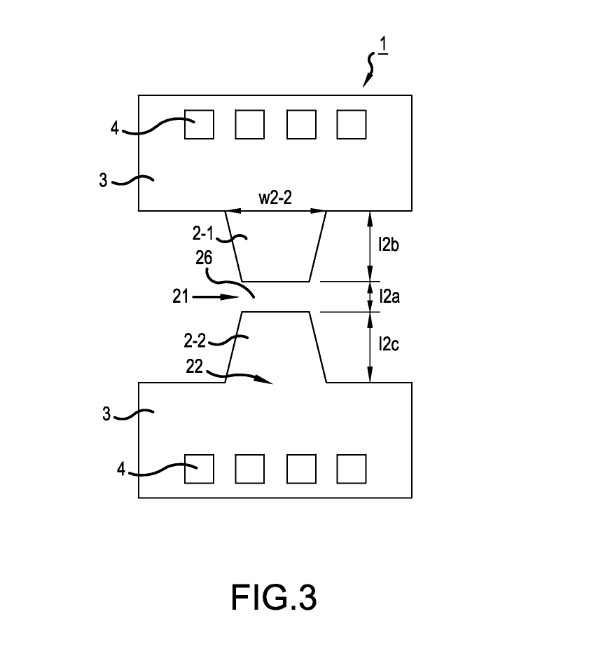

Next, the polysilicon fuse trimming mechanism will be described. FIG. 3 is a plan view showing a state in which the polysilicon fuse in FIG. 2 has been blown. The trimming of the polysilicon fuse means that a part of the polysilicon fuse is melted down. The polysilicon fuse can be trimmed when the first place 21 of the polysilicon resistor 1 is replaced by the oxide film. Specifically, when a voltage is applied between the low resistance conductors 3 of the polysilicon resistor 1, the high resistance conductor 2 serves as the current path so that a current can flow from one low resistance conductor 3 to the other low resistance conductor 3 through the high resistance conductor 2. Thus, Joule heat is generated in the polysilicon resistor 1. On this occasion, the temperature of the high resistance conductor 2 is higher than that of each of the low resistance conductors 3 so that the temperature of the first place 21 of the high resistance conductor 2 becomes the highest.

The polysilicon in the vicinity of the first place 21 of the high resistance conductor 2 is melted and liquefied when the temperature exceeds about 1,400° C., and evaporated when the temperature exceeds about 2,300° C. The liquefied polysilicon is contracted due to surface tension and electromigration to tend to move toward the low resistance conductors 3 in the opposite ends to thereby gather like islands. In addition, the liquefied polysilicon is higher in density and decreased in volume by about 10% than the solid polysilicon. Thus, a region (gap) where the polysilicon is substantially absent is partially generated in the vicinity of the first place 21 of the high resistance conductor 2 due to the movement and the volume decrease of the polysilicon caused by the liquefaction of the polysilicon and the evaporation of the polysilicon caused by gasification of the polysilicon. On the other hand, the portion of the silicon oxide film covering the polysilicon resistor 1 is melted at about 1,600° C. and flows into the gap generated in the vicinity of the first place 21 of the high resistance conductor 2.

Since the silicon oxide film flows into the gap generated in the vicinity of the first place 21 of the high resistance conductor 2, the first place 21 of the high resistance conductor 2 is replaced by the silicon oxide film. Therefore, the polysilicon resistor 1 is melted down in the first place 21 of the high resistance conductor 2. When the high resistance conductor 2 is melted down, the current path of the polysilicon resistor 1 is cut off. Therefore, the generation of Joule heat in the polysilicon resistor 1 is suspended, and the temperature of the polysilicon resistor 1 starts to decrease. When the temperature of the polysilicon resistor 1 decreases, the liquefied polysilicon and the liquefied silicon oxide film become solid. Therefore, the polysilicon resistor 1 is solidified in a state in which the polysilicon resistor 1 is cut into two in the vicinity of the first place 21 of the high resistance conductor 2. Thus, the trimming of the polysilicon fuse is completed.

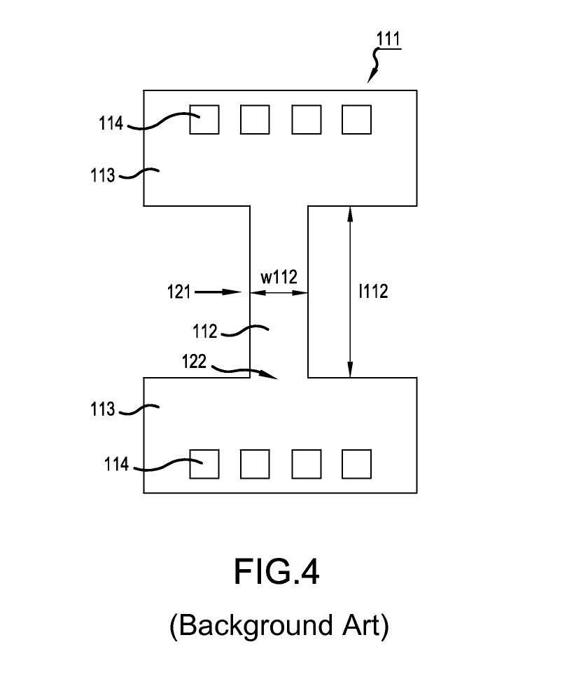

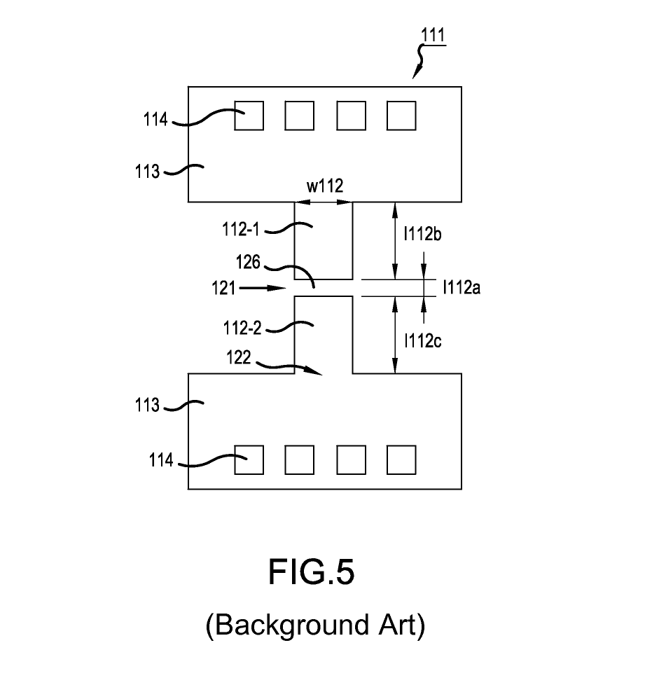

Then, a state of the polysilicon fuse according to Embodiment 1 after trimming will be described in comparison with the background-art structure. FIG. 4 is a plan view showing a planar structure of a polysilicon fuse according to the background art. FIG. 5 is a plan view showing a state in which the polysilicon fuse in FIG. 4 has been blown. As shown in FIG. 3, the high resistance conductor 2 of the polysilicon resistor 1 according to the invention is cut into two in the vicinity of the first place 21, as described in the polysilicon fuse trimming mechanism. For example, the total volume of the high resistance conductor 2 is decreased by 10% due to liquefaction of the polysilicon so that a region (gap) 26 where polysilicon is substantially absent can be formed in the vicinity of the first place 21 of the high resistance conductor 2. For example, assume that the liquefied polysilicon has been separated into the sides of the low resistance conductors 3 opposed to each other with respect to the high resistance conductor 2 (for example, vertically in FIG. 3). In the case where the width w2-1 of the first place 21 of the high resistance conductor 2 is, for example, about 1.0 the width w2-2 of the second place 22 of the high resistance conductor 2 is, for example, about 2.0 and the length l2 of the high resistance conductor 2 is, for example, 2.0 μm, an interval l2a of the gap 26 becomes, for example, 0.28 Each of lengths l2b and l2c of two high resistance conductor parts 2-1 and 2-2 into which the high resistance conductor 2 has been cut becomes, for example, 0.86 μm (l2=l2a+l2b+l2c).

On the other hand, as shown in FIGS. 4 and 5, in a polysilicon resistor 111 according to the background-art structure, a high resistance conductor 112 has a substantially rectangular planar shape in which widths w112 of a first place 121 and a second place 122 of the high resistance conductor 112 are equal to each other. Also in the polysilicon resistor 111, the total volume of the high resistance conductor 112 is decreased, for example, by 10% due to liquefaction of the polysilicon so that a region (gap) 126 where polysilicon is substantially absent can be formed in the vicinity of the first place 121 of the high resistance conductor 112. For example, assume that the liquefied polysilicon has been separated into the sides of low resistance conductors 113 opposed to each other with respect to the high resistance conductor 112 (for example, vertically in FIG. 5). The first place 121 of the high resistance conductor 112 corresponds to a central portion of the high resistance conductor 112 in a direction parallel to a current path of the polysilicon resistor 111. Each of the second places 122 of the high resistance conductor 112 corresponds to an interface between the high resistance conductor 112 and the corresponding low resistance conductor 113. The reference numeral 114 represents a contact electrode. In the case where a width w112 of the high resistance conductor 112 is, for example, about 1.0 μm and a length l112 of the high resistance conductor 112 is, for example, 2.0 an interval l112a of a gap 126 becomes, for example, 0.20 Each of lengths l112b and l112c of two high resistance conductor parts 112-1 and 112-2 into which the high resistance conductor 112 has been cut becomes, for example, 0.90 μm (l112=l112a+l112b+l112c).

Thus, in the invention, the interval l2a of the gap 26 generated in the vicinity of the first place 21 of the high resistance conductor 2 can be made wider by 40% than the interval l112a of the gap 126 generated in the vicinity of the first place 121 of the high resistance conductor 112 in the background-art structure. The reason is as follows. FIGS. 6A and 6B are plan views showing a half part of a high resistance conductor of a polysilicon resistor constituting a polysilicon fuse of a semiconductor device according to the invention and the background art, respectively. The trapezoidal shape part (hereinafter referred to as trapezoidal shape part 2) corresponding to the lower half of the high resistance conductor 2 in FIG. 2 is shown in FIG. 6A. In addition, a rectangular shape part (hereinafter referred to as rectangular shape part 112) corresponding to the lower half of the high resistance conductor 112 according to the background-art structure in FIG. 4 is shown as comparison in FIG. 6B. That is, a length t0 of the trapezoidal shape part 2 according to the invention is equal to half the length l2. A length t2 of the rectangular shape part 112 according to the background-art structure is equal to half the length l112.

The width w2-1 of the first place 21 of the trapezoidal shape part 2 according to the invention is narrower than the width w2-2 of the second place 22. Therefore, in the case where, for example, the trapezoidal shape part 2 is divided into 10%-volume portions each having a volume of 10% to the total volume of the trapezoidal shape part 2 and in parallel with the bottom portion, the width of the 10%-volume portion on the side of the first place 21 of the trapezoidal shape part 2 exceeds the width of the 10%-volume portion on the side of the second place 22 of the trapezoidal shape part 2. On the other hand, the widths w112 of the first place 121 and the second place 122 of the rectangular shape part 112 according to the background-art structure are equal to each other. Therefore, in the case where, for example, the rectangular shape part 112 is divided into 10%-volume portions each having a volume of 10% to the total volume of the rectangular shape part 112 and in parallel with the bottom portion, the widths of the 10%-volume portions of the rectangular shape part 112 are equal independently of the positions of the 10%-volume portions in the rectangular shape part 112.

Here, the gap generated due to melting of polysilicon in the vicinity of the first place of the high resistance conductor will be assumed as follows. As shown in FIG. 6A, in the invention a 10%-volume portion (hatched portion S1) corresponding to a volume of 10% to the total volume of the trapezoidal shape part 2 is melted from the first place 21 of the trapezoidal shape part 2, and turned into the gap 26 (the region which appears in the vicinity of the first place 21 of the high resistance conductor 2 and from which the polysilicon is substantially absent). In addition, as shown in FIG. 6B, in the background-art structure, a 10%-volume portion (hatched portion S2) corresponding to a volume of 10% to the total volume of the rectangular shape part 112 is melted from the first place 121 of the rectangular shape part 112, and turned into the gap 126.

In this case, as described above, the widths of the 10%-volume portions of the trapezoidal shape part 2 vary from one portion to another along the part 2 while the widths of the 10%-volume portions of the rectangular shape part 112 are equal independently of the positions along the part 112. Accordingly, a ratio (=t1/t0) of the width t1 of the hatched portion S1 of the trapezoidal shape part 2 to the total width t0 of the trapezoidal shape part 2 is larger than a ratio (=t3/t2) of the width t3 of the hatched portion S2 of the rectangular shape part 112 to the total width t2 of the rectangular shape part 112. That is, when the total width t0 of the trapezoidal shape part 2 and the total width t2 of the rectangular shape part 112 are equal to each other (t0=t2), the width t1 of the hatched portion S1 of the trapezoidal shape part 2 exceeds the width t3 of the hatched portion S2 of the rectangular shape part 112 (t1>t3). Accordingly, the interval l2a of the gap 26 formed due to melting of the hatched portion S1 according to the invention is wider than the interval l112a of the gap 126 formed due to melting of the hatched portion S2 according to the background-art structure. Thus, the interval l2a of the gap 26 can be made wider than that according to the background-art structure. Accordingly, the polysilicon resistor 1 can be cut off more surely than that according to the background-art structure. Although the term “width” is used to denote the dimensions t0-t3 above, this does not necessarily require that dimensions t0-t3 be the smaller dimension from side to side.

As described above, according to Embodiment 1, of the high resistance conductor whose resistance is higher than any other portion (any low resistance conductor) of the polysilicon resistor constituting the polysilicon fuse, the width of the first place reacting most actively when a current flows in the polysilicon resistor is made narrower than the width of the second place serving as an interface with the low resistance conductor. Accordingly, a distance between blown faces of the polysilicon fuse can be made longer than that according to the background art, in spite of a low voltage (for example, about 5V to 10V) used internally in a semiconductor integrated circuit. Thus, the polysilicon resistor constituting the polysilicon fuse can be cut off more surely than that according to the background-art structure. In addition, according to Embodiment 1, the polysilicon resistor can be cut off by a low voltage used internally in a semiconductor integrated circuit. Accordingly, the characteristic of the circuit can be adjusted accurately after the polysilicon fuse is incorporated into a package. Polysilicon fuses may be trimmed in the form of a wafer which has not been diced into individual chips.

In addition, according to Embodiment 1, an etching mask used in an etching process for making a cavity in the periphery of the polysilicon resistor or a cover plate of the polysilicon resistor is dispensable. Thus, the cost can be prevented from increasing. Accordingly, a highly reliable polysilicon fuse can be provided inexpensively. For example, when the polysilicon fuse is used for detection of an overcurrent for an IPM (Intelligent Power Module), a highly reliable storage portion can be provided more inexpensively than when an EPROM (Erasable Programmable Read Only Memory) is used. In addition, according to Embodiment 1, a similar effect can be achieved also when the polysilicon fuse is trimmed by a high voltage in the same manner as in the background art.

### Embodiment 2

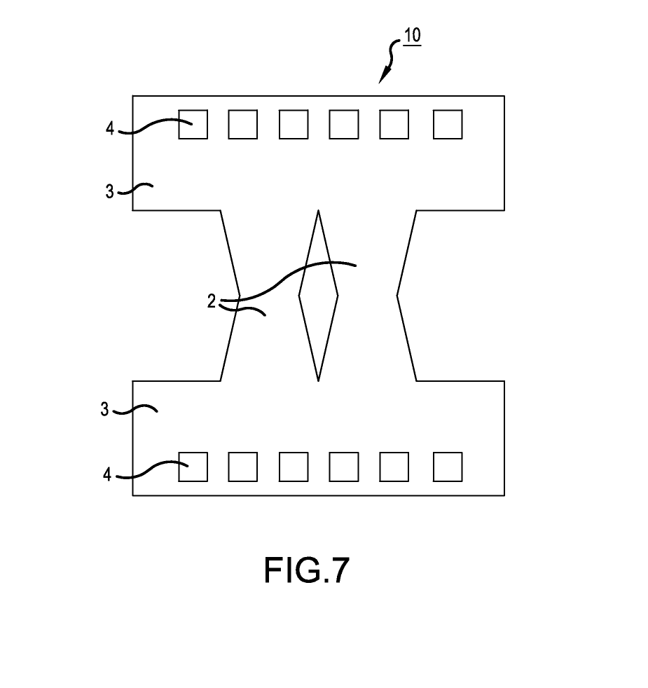

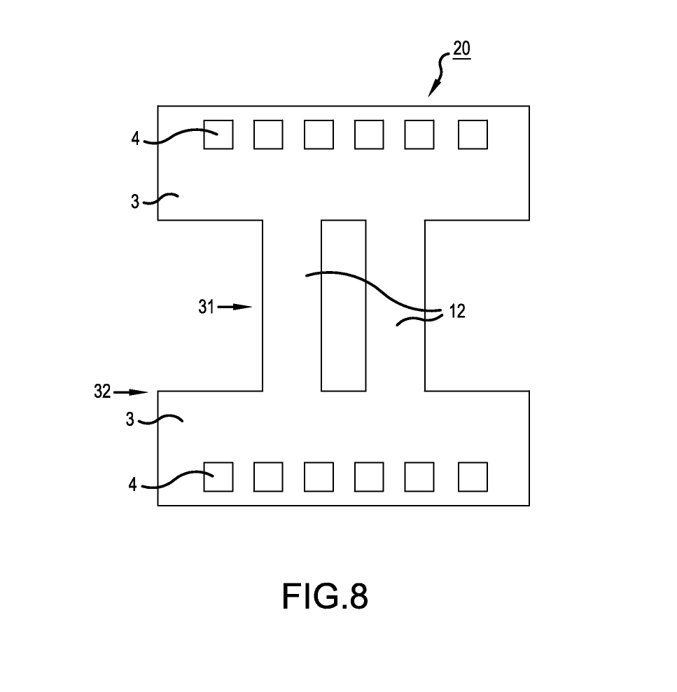

Next, a structure of a semiconductor device according to Embodiment 2 will be described. FIG. 7 is a plan view showing a planar structure of a polysilicon fuse provided in the semiconductor device according to Embodiment 2. FIG. 8 is a plan view showing a planar structure of another example of the polysilicon fuse provided in the semiconductor device according to Embodiment 2. A different point of the semiconductor device according to Embodiment 2 from the semiconductor device according to Embodiment 1 is that a plurality of high resistance conductors 2 are provided between opposite low resistance conductors 3 of a polysilicon resistor 10. The plurality of high resistance conductors 2 are provided in parallel with one another in a direction perpendicular to a current path of the polysilicon resistor 10. Thus, a plurality of current paths (high resistance conductors 2) are formed between opposite contact electrodes 4 with respect to the high resistance conductors 2. When two or more high resistance conductors 2 are arranged in parallel in this manner, it is more difficult for heat to escape from the high resistance conductors 2.

In addition, as shown in FIG. 8, a plurality of high resistance conductors 12 each substantially having a rectangular planar shape in which a width of a first place 31 and a width of a second place 32 are equal to each other may be provided in parallel between opposite low resistance conductors 3 of a polysilicon resistor 20. The first place 31 of each high resistance conductor 12 corresponds to a central portion of the high resistance conductor 12 in a direction parallel to a current path of the polysilicon resistor 20. The second place 32 of the high resistance conductor 12 corresponds to an interface between the high resistance conductor 12 and the low resistance conductor 3.

As described above, according to Embodiment 2, a similar effect to that according to Embodiment 1 can be obtained.

In the above description, the invention is not limited to the aforementioned embodiments but can be changed variously without departing from the spirit and scope of the invention. For example, although a polysilicon fuse constituted by a resistor made from polysilicon has been described by way of example in the embodiments, a resistor made from a material which can be contracted when the material is liquefied may be used in place of polysilicon to form a fuse. In addition, although each of the embodiments has a configuration in which the first place is set as an intersection line in each side surface of the high resistance conductor, and a predetermined angle is made between a side surface of one trapezoidal shape part and a side surface of the other trapezoidal shape part (that is, each of the trapezoidal shape parts has a planar shape substantially formed into an isosceles trapezoidal shape), the invention is not limited thereto. Alternatively, configurations may be made so that the first place is set as an intersection line in only one side surface of the high resistance conductor and a predetermined angle is made between a side surface of one trapezoidal shape part and a side surface of the other trapezoidal shape part. In addition, although the case where the storage portion is constituted by polysilicon fuses has been described by way of example in the embodiments, the invention is not limited thereto. For example, a reference voltage may be adjusted by means of the polysilicon fuse according to the invention.

As described above, the semiconductor device according to embodiments of the invention is useful for a power semiconductor device used for detection of an overcurrent for an IPM, etc. in any power conversion device or any of power supply devices of various industrial machines etc.

What is claimed is:

1. A semiconductor device comprising:
a substrate;
an insulating film disposed on the substrate;
a fuse disposed on the insulating film; and
an oxide film disposed on the fuse, the fuse comprising a first resistor, a second resistor adjacent to a first end portion of the first resistor and having a lower resistance than the first resistor, and a third resistor adjacent to a second end portion of the first resistor and having a lower resistance than the first resistor,
wherein a width of the first resistor decreases gradually from the first end potion and the second end portion toward a central portion of the first resistor.

2. A semiconductor device according to claim 1, wherein:
the first resistor has a planar shape comprising two trapezoidal parts, each of which comprises the central portion as an upper bottom and an interface with the second resistor or an interface with the third resistor as a lower bottom are arranged so that the upper bottoms can face each other.

3. A semiconductor device according to claim 2, wherein:
an angle between a side surface of one trapezoidal part comprising an interface between the first resistor and the second resistor as a lower bottom and a side surface of the other trapezoidal part comprising an interface between the first resistor and the third resistor as a lower bottom is larger than 90°.

4. A semiconductor device according to claim 1, wherein:
the first resistor forms a current path between the second resistor and the third resistor; and
the central portion of the first resistor is a portion of the first resistor where heat is generated most due to the flowing of the current.

5. A semiconductor device according to claim 4, wherein:
a width of the first resistor in a direction perpendicular to the current path is narrower than each of a width of the second resistor and a width of the third resistor in the direction perpendicular to the current path.

6. A semiconductor device according to claim 1, wherein:
a plurality of first resistors are formed in parallel with one another in a direction perpendicular to a current path.

7. A semiconductor device according to claim 1, wherein:
the first resistor comprises polycrystalline silicon.

8. A semiconductor device according to claim 1, wherein:
an angle between a side surface of one trapezoidal part comprising an interface between the first resistor and the second resistor as a lower bottom and a side surface of the other trapezoidal part comprising an interface between the first resistor and the third resistor as a lower bottom is larger than 90°.
